(19) United States
(12) Patent Application Publication
(10) Pub. No.: US 2025/0384939 A1
(43) Pub. Date: Dec. 18, 2025

(54) SUSPENDING WITHIN PROGRAM-VERIFY OPERATIONS FOR SHORTER WAIT TIME TO SUSPEND

(71) Applicant: Micron Technology, Inc., Boise, ID (US)

(72) Inventors: Sanjoy Jena, Singapore (SG); Narayanan Ramanan, Hyderabad (IN); Kapil Verma, San Jose, CA (US)

(21) Appl. No.: 19/218,963

(22) Filed: May 27, 2025

(30) Foreign Application Priority Data
Jun. 12, 2024 (IN) 202441045346

(51) Int. Cl. G11C 16/34; G11C 11/56; G11C 16/04; G11C 16/10

(52) U.S. Cl. CPC G11C 16/3459; G11C 11/5628; G11C 11/5671; G11C 16/0483; G11C 16/10

(57) ABSTRACT

A memory device includes a memory array having a plurality of memory cells. Control logic operatively is coupled with the memory array. The control logic receives a suspend command while programming multiple data states to a set of the plurality of memory cells of the memory array. The control logic determines whether a trim value associated with a program suspend operation is less than a total number of program verify operations to be performed during a present program verify loop of a programming operation. The control logic, in response to the trim value being less than the total number of program verify operations, causing only a subset of the total number of program verify operations that correspond to the trim value to be performed before causing a program suspend operation to be performed on the set of plurality of memory cells.

### CLAIM OF PRIORITY

The present application claims the benefit under 35 U.S.C. § 119 (a) of Indian Provisional Patent Application No. 202441045346, filed Jun. 12, 2024, which is incorporated by this reference herein.

### TECHNICAL FIELD

Embodiments of the disclosure are generally related to memory sub-systems, and more specifically, relate to suspending within program-verify operations for shorter wait time to suspend.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of some embodiments of the disclosure.

FIG. 1A illustrates an example computing system that includes a memory sub-system in accordance with some embodiments.

FIG. 1B is a block diagram of a memory device in communication with a memory sub-system controller of a memory sub-system according to an embodiment.

FIG. 2A-2B are schematics of portions of an array of memory cells as could be used in a memory of the type described with reference to FIG. 1B according to an embodiment.

FIG. 3 is a diagrammatic illustration that depicts memory cell populations for a triple-level cell (TLC) memory according to at least one embodiment.

FIG. 4 is a timing diagram depicting a portion of a programming operation to program selected TLC memory cells to target threshold voltages according to an embodiment.

FIG. 5 is a diagrammatic illustration that depicts pulse breakpoints and corresponding resume points according to at least one embodiment.

FIG. 6 is a diagrammatic illustration that depicts program verify (PV) breakpoints and corresponding resume points according to at least one embodiment.

FIG. 7 is a diagrammatic illustration that depicts customizable trim values that enable reduction of wait time to suspend with a variable number of program verify operations prior to suspend according to some embodiments.

FIG. 8 is a flow diagram of an example method of determining a number of program verify operations to perform within a program verify loop before suspend based on a trim value and a total number of program verify operations according to some embodiments.

FIG. 9 is a flow diagram of an example method of selectively choosing a trim value, based on a page belonging to a particular group of wordlines, for use in determining how many program verify operations to perform before suspend according to some embodiments.

FIG. 10 is a block diagram of an example computer system in which embodiments of the present disclosure can operate.

### DETAILED DESCRIPTION

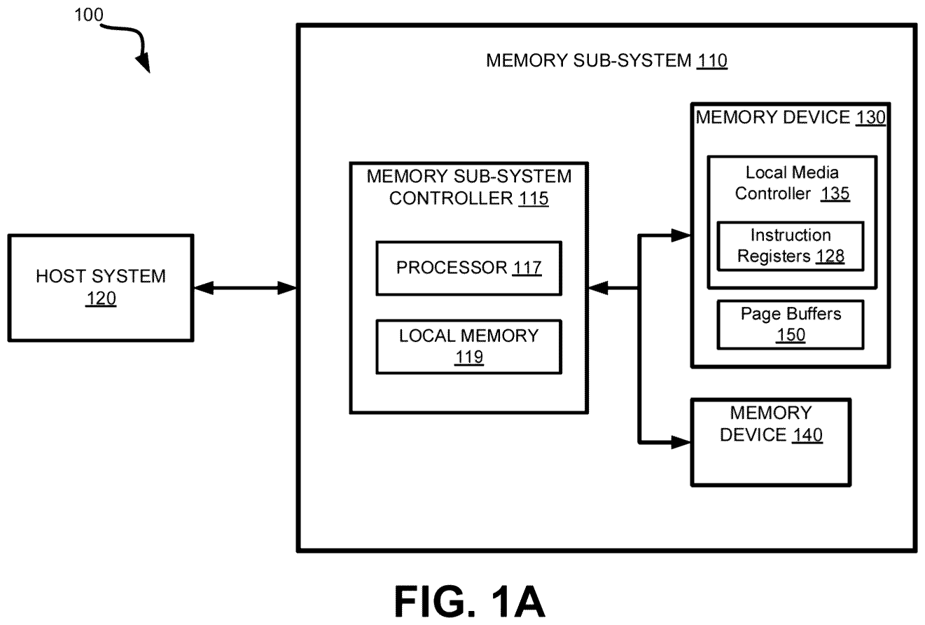

Embodiments of the present disclosure are directed to memory devices employing program suspend-resume operations that reduce wait time to suspend within program verify operations. A memory device can be a non-volatile memory device. One example of non-volatile memory devices is a negative-and (NAND) memory device, which is an example of a flash memory device. Other examples of non-volatile memory devices are described below in conjunction with FIG. 1A. These memory devices include memory cells to store data. For example, changes in threshold voltage (Vt) of the memory cells, through programming (which is often referred to as writing) of charge storage structures (e.g., floating gates or charge traps) or other physical phenomena (e.g., phase change or polarization), determine the data state (or data value) of each memory cell.

In programming memory, memory cells can generally be programmed as single-level cells (SLC) or multiple-level cells (MLC). Thus, data states may be associated with certain logical levels of multi-cell memory such as L0, L1, L2, and so forth. Single-level cells can use a single memory cell to represent one digit (e.g., bit) of data. For example, in SLC, a Vt of 2.5V can indicate a programmed memory cell (e.g., representing a logical 0) while a Vt of −0.5V can indicate an erased cell (e.g., representing a logical 1). As an example, the erased state in SLC can be represented by any threshold voltage less than or equal to 0V, while the programmed data state can be represented by any threshold voltage greater than 0V. Multiple-level cells use more than two Vt ranges, where each Vt range indicates a different data state (or logical level). A margin (e.g., a certain number of volts) such as a dead space can separate adjacent Vt ranges to facilitate differentiating between data states. Multiple-level cells can take advantage of the analog nature of traditional non-volatile memory cells by assigning a bit pattern to a specific Vt range.

In programming MLC memory, data values are often programmed using more than one pass, e.g., programming one or more digits in each pass. For example, in four-level MLC (typically referred to simply as MLC), a first digit, e.g., a least significant bit (LSB), which is often referred to as lower page (LP) data, can be programmed to the memory cells in a first pass, thus resulting in two (e.g., first and second) threshold voltage ranges. Subsequently, a second digit, e.g., a most significant bit (MSB), which is often referred to as upper page (UP) data can be programmed to the memory cells in a second pass, typically moving some portion of those memory cells in the first threshold voltage range into a third threshold voltage range, and moving some portion of those memory cells in the second threshold voltage range into a fourth threshold voltage range. Similarly, eight-level MLC (typically referred to as TLC) can represent a bit pattern of three bits, including a first digit, e.g., a least significant bit (LSB) or lower page (LP) data; a second digit, e.g., upper page (UP) data; and a third digit, e.g., a most significant bit (MSB) or extra page (XP) data. In operating TLC, the LP data can be programmed to the memory cells in a first pass, resulting in two threshold voltage ranges, followed by the UP data and the XP data in a second pass, resulting in eight threshold voltage ranges. Similarly, sixteen-level MLC (typically referred to as QLC) can represent a bit pattern of four bits, and 32-level MLC (typically referred to as PLC) can represent a bit pattern of five bits.

To program a group of memory cells to each Vt state of SLC or MLC memory, according to some embodiments, a local media controller (e.g., control logic) of some memory devices causes different voltage levels to be applied to data lines (or bitlines) that causes selected memory cell(s), such as a population of memory cells, to be programmed. In these embodiments, the control logic can send a control signal to a signal driver that is selectively connected between a page buffer and a bitline. The page buffer can provide voltage levels to the signal driver that the signal driver can use, when turned on by the control signal, to generate a voltage on the bitline that programs a selected memory cell of the group of memory cell(s). These voltage levels can vary in voltage depending on a level (or speed) of programming to occur, as will be explained.

In some embodiments, programming the memory cells can occur in programming schemes referred to as selective slow programming convergence (SSPC). In SSPC programming, for example, memory cells nearer to their respective intended data states are programmed more slowly (e.g., partially enabled for programming) compared to memory cells farther from their respective intended data states (e.g., fully enabled for programming) while receiving a same voltage level at their respective control gates. A target voltage can correspond to a minimum threshold voltage for a target Vt level, which can be referred to as the program verify (PV) voltage for the target voltage. A pre-program verify (PPV) voltage can be selected to be less than the PV voltage to enable SSPC programming between the PV voltage and the PPV voltage.

Depending on how close memory cells are from the target voltage, the page buffers can be directed to provide a bias voltage to the memory cells (via signal drivers) to selectively control the voltage levels actually being applied to the group or population of memory cells. As the memory cells get closer to their respective target voltages, the applied bias voltages generally increase so that the actual programming pulse voltages decrease, slowing down the programming rate. For example, three bias voltages can correspond to at least three voltage levels, including non-SSPC programming (e.g., before reaching the PPV voltage), SSPC programming performed between the PPV and PV voltage levels, and inhibited from programming. Of these three bias voltages, any given page buffer may provide one of the bias voltages at any given time depending on a phase of SSPC-related programming in which the memory cells are being programmed by that particular page buffer. These bias voltages can also be applied during program verify operations associated with determining how close the memory cells have been programmed to the target voltage, which can then lead to switching to apply a different, perhaps slower programming, voltage bias level for a subsequent phase of SSPC programming. Because different data states (or levels) of programming may be performed in parallel depending on the subset of memory cells and programming progress, multiple program verify operations can be performed between SSPC-based programming pulses.

In most memory devices, a read operation is faster than an program operation, and read operations can be given priority over program operations. For this reason, program operations are often repeatedly interrupted when a host system (or coupled memory sub-system controller, e.g., processing device) sends a suspend command in order to temporarily suspend the program operation in favor of performing read operations and/or other non-program memory operations during a suspend period. Upon completion of the read operation, a program resume command can be issued to resume and complete a program operation that had been suspended. In certain memory devices, information related to SSPC-classified cells at suspend is lost and it can be difficult to determine how to resume the programming of such memory cells.

In certain memory devices, the program operation can be suspended at one of two breakpoints, either at the end of program verify operations (referred to as a verify suspend point) or at the end of a programming pulse (pulse suspend point). There can thus be a delay between receipt of a suspend command and the beginning of a program suspend operation, e.g., based on being forced to begin suspend at particular breakpoints. There can be a further delay between the start of the program suspend operation and being able to handle non-program operations, e.g., to get to the point of releasing a ready/busy signal (RBSY) of the memory device so that non-program operations can proceed. This further delay can include, but not be limited to, time to enable program voltages to discharge and time to prepare charge pumps, regulators, and other page buffer hardware to shift from programming to, e.g., reading or erasing memory cells. There can be a still further delay to complete a certain number of non-program operations that may be prioritized over programming operations. In some cases, a set duration of the suspend state is enforced so that, e.g., a certain number of non-program operations can be completed before resuming programming.

In such memory devices, charge loss can occur during a program suspend operation as a result of delays for preparing to suspend and while one or more non-program operations (such as read operations) are being performed, causing threshold voltage (Vt) downshift in memory cells. This Vt downshift can cause some of the memory cells to be misclassified as program/selective slow programming convergence (or PGM/SSPC) at the time of performing a resume verify operation. The misclassification can make these memory cells receive an effective gate-step voltage much larger than intended, leading to program voltage overshoot and a corresponding state-width degradation or read-window loss. The program voltage overshoot can also cause undesired strain on memory cells, which can shorten their effective lives.

In some memory devices, in response to a suspend command, stopping the program operation at the pulse suspend point leads to loss of cell Vt information due to a lack of a succeeding verify operation before suspend. Thus, similar to just discussed, as the Vt of memory cells are not tracked, the memory cells can tend to receive a higher effective gate-step than intended, leading to overshoot and a corresponding read-window loss. Stopping the program at the verify suspend point, however, helps to at least partially track the cell Vt across a program suspend operation and thus reduces read-window loss. Suspending programming at the verify suspend point comes at a cost of more wait time for the suspend command to be serviced due to ongoing verify operations, which is not preferred for low-latency, demanding workloads.

Aspects of the present disclosure address the above and other deficiencies by modifying when to activate a program suspend operation in response to a suspend command by introducing one or more new suspend points (also referred to as breakpoints) within a program verify loop, e.g., and thus activate the program suspend operations at a verify loop suspend point. The particular verify loop suspend point to be used may depend on a trim value that is set (e.g., programmed) to the memory device based on particular criteria, such as speed of programming, number of data states, different pulse and verify durations, and the like. Embodiments may be related to multi-level cell programming such that there are often multiple program verify operations performed between programming pulses, e.g., each performed for a different data state (or programming level). Thus, depending on the trim value, a more-targeted execution of at least one of the program verify operations can improve Vt tracking, thus reducing overshoot, while also reducing wait time for executing the suspend operation because not all (e.g., a total number) of the program verify operations that were planned to be performed are actually performed.

In some embodiments, for example, a memory device includes a memory array having a plurality of memory cells. Control logic can be operatively coupled with the memory array. In embodiments, the control logic receives a suspend command while programming multiple data states to a set of the plurality of memory cells of the memory array. The control logic can determine whether a trim value associated with a program suspend operation is less than a total number of program verify operations to be performed during a present program verify loop of a programming operation. The control logic, in response to the trim value being less than the total number of program verify operations, may cause only a subset of the total number of program verify operations that correspond to the trim value to be performed before causing a program suspend operation to be performed on the set of plurality of memory cells. The control logic can also, in response to the trim value being greater than or equal to the total number of program verify operations, cause the total number of program verify operations to be performed before causing the program suspend operation to be performed on the set of plurality of memory cells. In this way, the trim value in combination with the total number of program verify operations to be performed between programming pulses can be used to determine how many program verify operations (e.g., to be performed for particular data states) are actually performed before the suspend operation is performed.

In different or additional embodiments, the control logic can also utilize a different trim value for different wordline groups in order to accommodate different wordline groups with different pulse and verify durations, which shortens wait times to suspend within a target requirement wait time. Thus, the control logic can determine with which group of wordlines of a plurality of wordlines is a page of a plurality of memory cells associated that is being programmed. The control logic can, in response to the page of the plurality of memory cells being associated with a first group of wordlines, select a first trim value corresponding to the first group of wordlines as a selected trim value. The control logic can, in response to the page of the plurality of memory cells being associated with a second group of wordlines, instead select a second trim value corresponding to the second group of wordlines as the selected trim value. This selective choice of a trim value depending on wordline group can be made for many different wordline groups, e.g., before employing the selected trim value to determine how many program verify operations are to be performed within a present program verify loop, as discussed previously. The control logic can then, after these program verify operations are performed, cause a program suspend operation to be performed on the page of the plurality of memory cells in response to the suspend command.

Therefore, advantages of the systems, devices, and methods implemented in accordance with some embodiments of the present disclosure include, but are not limited to, selective execution of a certain number of program verify operations between programming pulses during a program suspend operation. In this way, performing at least one (or more) but not necessarily all of the total number of program verify operations to be performed between a particular pair of programming pulses enables some level of Vt tracking while also reducing wait time to suspend due to not performing all of the total number of program verify operations. Due to at least partial tracking of Vt values for the memory cells, program overshoot is also significantly diminished, providing a strong balance in programming outcomes between those typically achieved by activating a suspend operation only at either the pulse suspend point or the program verify suspend point. Other advantages will be apparent to those skilled in the art of memory programming, to include selective slow program convergence and program suspend-resume operations, associated with a memory device discussed hereinafter.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such media or memory devices. The memory sub-system 110 can be a storage device, a memory module, or a hybrid of a storage device and memory module.

The memory device 130 can be a non-volatile memory device. One example of non-volatile memory devices is a negative-and (NAND) memory device. A non-volatile memory device is a package of one or more dice. Each die can include one or more planes. Planes can be groups into logic units (LUN). For some types of non-volatile memory devices (e.g., NAND devices), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1,” or combinations of such values.

The memory device 130 can be made up of bits arranged in a two-dimensional or three-dimensional grid, also referred to as a memory array. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface, Open NAND Flash Interface (ONFI) interface, or some other interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130,140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which includes a raw memory device 130 having control logic (e.g., local media controller 135) on the die and a controller (e.g., memory sub-system controller 115) for media management within the same memory device package. An example of a managed memory device is a managed NAND (MNAND) device.

In some embodiments, the memory device 130 includes page buffers 150, which can be used to program data to the memory cells of the memory device 130 and to read the data out of the memory cells. Control logic of the local media controller 135 can be configured to coordinate the timing and manner of performing one or more data state-based program verify operations based on a related trim value, which can be selectively chosen for particular wordline groups, before activating a program suspend operation in response to a suspend command while programming a set of memory cells. For example, the program verify operations can be performed in between programming pulses for particular data states that are undergoing a current SSPC-programming operation.

In at least some embodiments, the local media controller 135 (e.g., control logic) includes instruction registers 128, which represent computer-usable memory for storing computer-readable instructions. For some embodiments, the instruction registers 128 represent firmware. Alternatively, the instruction registers 128 represent a grouping of memory cells, e.g., reserved block(s) of memory cells, of an array of memory cells 104 (see FIG. 1A).

FIG. 1B is a simplified block diagram of a first apparatus, in the form of a memory device 130, in communication with a second apparatus, in the form of a memory sub-system controller 115 of a memory sub-system (e.g., the memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), can be a memory controller or other external host device.

The memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line can be associated with more than one logical row of memory cells and a single data line can be associated with more than one logical column. Memory cells (not shown in FIG. 1B) of at least a portion of the array of memory cells 104 are capable of being programmed to one of at least two target data states.

Row decode circuitry 108 and column decode circuitry 111 are provided to decode address signals. Address signals are received and decoded to access the array of memory cells 104. The memory device 130 also includes input/output (I/O) control circuitry 112 to manage input of commands, addresses and data to the memory device 130 as well as output of data and status information from the memory device 130. An address register 114 is in communication with the I/O control circuitry 112 and row decode circuitry 108 and column decode circuitry 111 to latch the address signals prior to decoding. A command register 124 is in communication with the I/O control circuitry 112 and the local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations, and/or erase operations) on the array of memory cells 104. The local media controller 135 is in communication with row decode circuitry 108 and column decode circuitry 111 to control the row decode circuitry 108 and column decode circuitry 111 in response to the addresses.

The local media controller 135 is also in communication with a cache register 118 and a data register 121. The cache register 118 latches data, either incoming or outgoing, as directed by the local media controller 135 to temporarily store data while the array of memory cells 104 is busy writing or reading, respectively, other data. During a program operation (e.g., write operation), data can be passed from the cache register 118 to the data register 121 for transfer to the array of memory cells 104; then new data can be latched in the cache register 118 from the I/O control circuitry 112. During a read operation, data can be passed from the cache register 118 to the I/O control circuitry 112 for output to the memory sub-system controller 115; then new data can be passed from the data register 121 to the cache register 118. The cache register 118 and/or the data register 121 can form (e.g., can form at least a portion of) the page buffers 150 of the memory device 130. The page buffers 150 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to the memory sub-system controller 115.

The memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) can be used in the various embodiments.

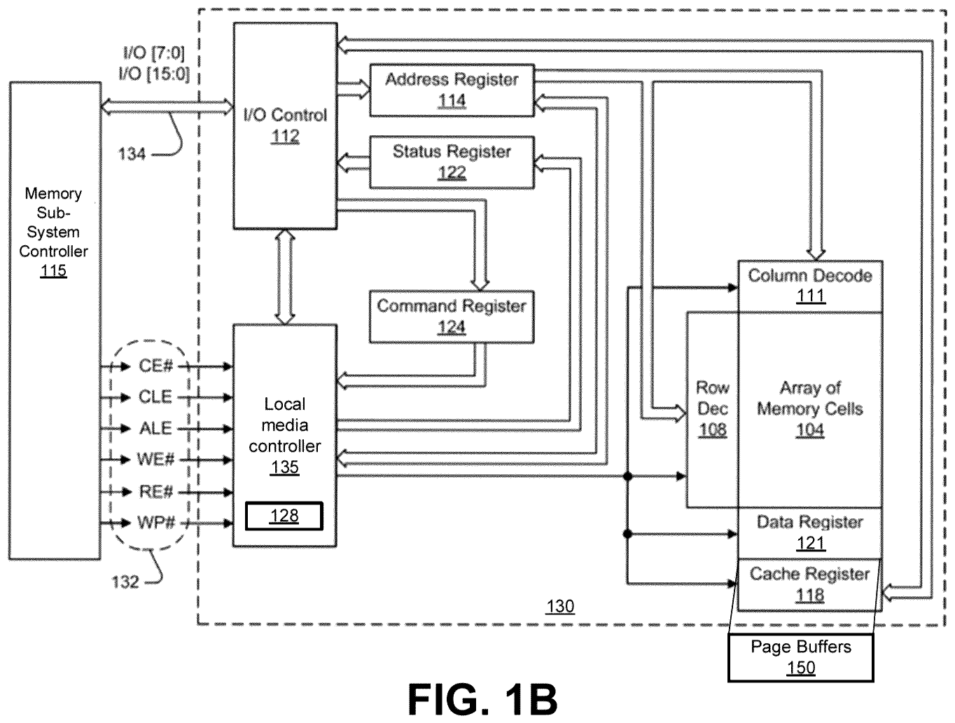

FIG. 2A-2C are schematics of portions of an array of memory cells 200A, such as a NAND memory array, as could be used in a memory of the type described with reference to FIG. 1B according to an embodiment, e.g., as a portion of the array of memory cells 104. Memory array 200A includes access lines, such as wordlines 2020 to 202N, and data lines, such as bitlines 2040 to 204M. The wordlines 202 can be connected to global access lines (e.g., global wordlines), not shown in FIG. 2A, in a many-to-one relationship. For some embodiments, memory array 200A can be formed over a semiconductor that, for example, can be conductively doped to have a conductivity type, such as a p-type conductivity, e.g., to form a p-well, or an n-type conductivity, e.g., to form an n-well.

Memory array 200A can be arranged in rows (each corresponding to a wordline 202) and columns (each corresponding to a bitline 204). Each column can include a string of series-connected memory cells (e.g., non-volatile memory cells), such as one of NAND strings 2060 to 206M. Each NAND string 206 can be connected (e.g., selectively connected) to a common source (SRC) 216 and can include memory cells 2080 to 208N. The memory cells 208 can represent non-volatile memory cells for storage of data. The memory cells 208 of each NAND string 206 can be connected in series between a select gate 210 (e.g., a field-effect transistor), such as one of the select gates 2100 to 210M (e.g., that can be source select transistors, commonly referred to as select gate source), and a select gate 212 (e.g., a field-effect transistor), such as one of the select gates 2120 to 212M (e.g., that can be drain select transistors, commonly referred to as select gate drain). Select gates 2100 to 210M can be commonly connected to a select line 214, such as a source select line (SGS), and select gates 2120 to 212M can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 2080 of the corresponding NAND string 206. For example, the drain of select gate 2100 can be connected to memory cell 2080 of the corresponding NAND string 2060. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 2120 can be connected to the bitline 2040 for the corresponding NAND string 2060. The source of each select gate 212 can be connected to a memory cell 208N of the corresponding NAND string 206. For example, the source of select gate 2120 can be connected to memory cell 208N of the corresponding NAND string 2060. Therefore, each select gate 212 can be configured to selectively connect a corresponding NAND string 206 to the corresponding bitline 204. A control gate of each select gate 212 can be connected to select line 215.

The memory array 200A in FIG. 2A can be a quasi-two-dimensional memory array and can have a generally planar structure, e.g., where the common source 216, NAND strings 206 and bitlines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202N and selectively connected to even bitlines 204 (e.g., bitlines 2040, 2042, 2044, etc.) can be one physical page of the memory cells 208 (e.g., even memory cells) while memory cells 208 commonly connected to wordline 202N and selectively connected to odd bitlines 204 (e.g., bitlines 2041, 2043, 2045, etc.) can be another physical page of the memory cells 208 (e.g., odd memory cells).

Although bitlines 2043-2045 are not explicitly depicted in FIG. 2A, it is apparent from the figure that the bitlines 204 of the array of memory cells 200A can be numbered consecutively from bitline 2040 to bitline 204M. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 2020-202N (e.g., all NAND strings 206 sharing common wordlines 202). Unless expressly distinguished, a reference to a page of memory cells herein refers to the memory cells of a logical page of memory cells. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory of the type described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. The three-dimensional NAND memory array 200B can incorporate vertical structures which can include semiconductor pillars where a portion of a pillar can act as a channel region of the memory cells of NAND strings 206. The NAND strings 206 can be each selectively connected to a bitline 2040-204M by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bitline 204. Subsets of NAND strings 206 can be connected to their respective bitlines 204 by biasing the select lines 2150-215K to selectively activate particular select transistors 212 each between a NAND string 206 and a bitline 204. The select transistors 210 can be activated by biasing the select line 214. Each wordline 202 can be connected to multiple rows of memory cells of the memory array 200B. Rows of memory cells that are commonly connected to each other by a particular wordline 202 can collectively be referred to as tiers.

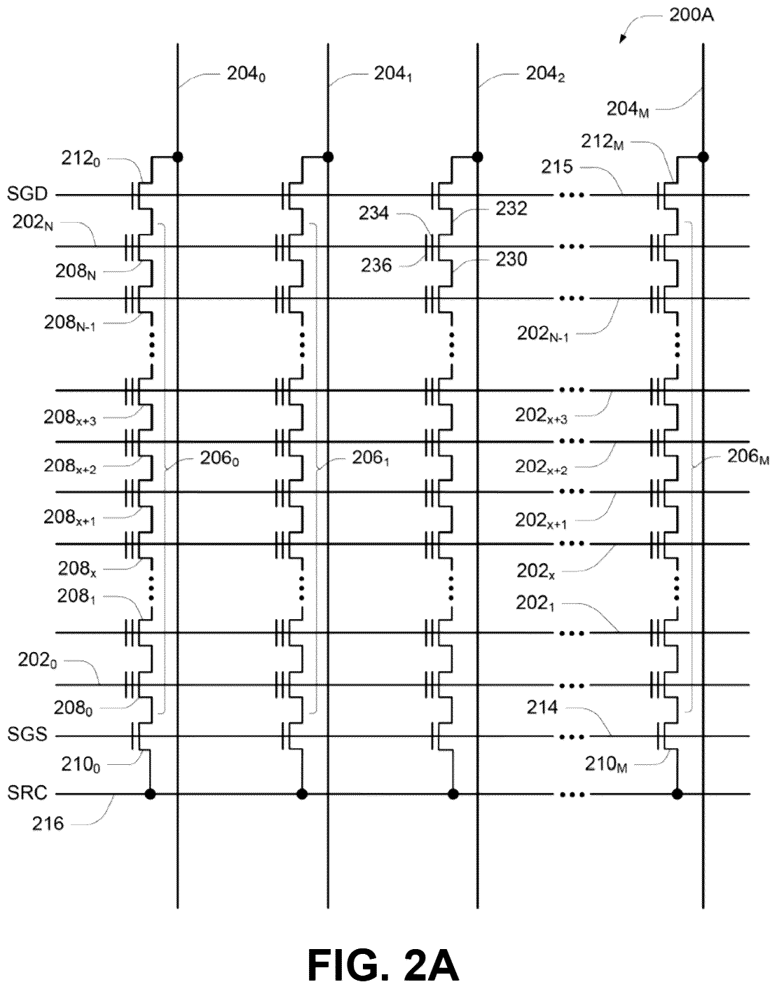

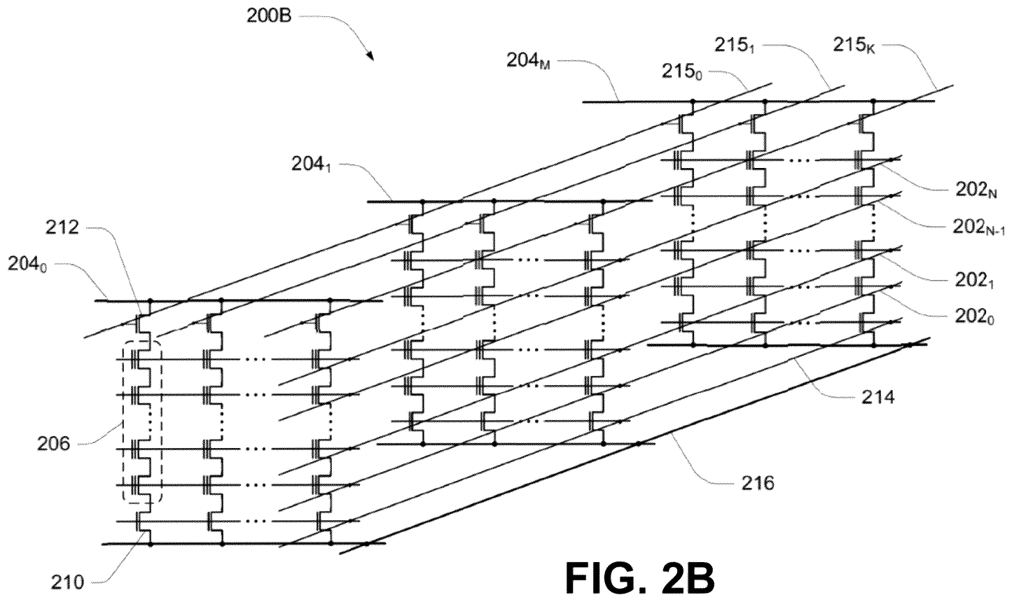

FIG. 3 is a diagrammatic illustration that depicts memory cell populations for a triple-level cell (TLC) memory according to at least one embodiment. For simplicity, FIG. 3 and the following FIG. 4 will presume programming operations for TLC memory cells, e.g., eight-level memory cells representing data states L0, L1, L2, L3, L4, L5, L6, and L7 using eight threshold voltage ranges, each representing a data state corresponding to a bit pattern of three digits. While discussed in reference to TLC memory cells, programming operations performed on lower storage density memory cells, e.g., SLC (two data states) or higher storage density memory cells, e.g., QLC (16 data states) or PLC (32 data states) memory cells, are equally applicable.

In this example, the population of memory cells 310 can be erased memory cells and represent a logical data value of ‘111’, the population of memory cells 311 can represent a logical data value of ‘011’, the population of memory cells 312 can represent a logical data value of ‘001’, the population of memory cells 313 can represent a logical data value of ‘101’, the population of memory cells 314 can represent a logical data value of ‘100’, the population of memory cells 315 can represent a logical data value of ‘000’, the population of memory cells 316 can represent a logical data value of ‘010’, and the population of memory cells 317 can represent a logical data value of ‘110’, where the right-most digit can represent the lower page data for a memory cell having a threshold voltage within the threshold voltage range of its respective population of memory cells, the center digit can represent the upper page data for that memory cell, and the left-most digit can represent the extra page data for that memory cell. Although a specific example of binary representation is provided, embodiments can use other arrangements of bit patterns to represent the various data states.

A read window between the population of memory cells 310 and the population of memory cells 311 is indicated at 320, which is the distance (e.g., in voltage) between adjacent Vt distributions for the memory cells representing data states L0 and L1. A read window between the population of memory cells 311 and the population of memory cells 312 is indicated at 321, which is the distance (e.g., in voltage) between adjacent Vt distributions for the memory cells representing data states L1 and L2. Likewise, a read window between the population of memory cells 312, 313, 314, 315, and 316, and the population of memory cells 313, 314, 315, 316, and 317 is indicated at 322, 323, 324, 325, and 326, respectively, which is the distance between adjacent Vt distributions for the memory cells representing data states L2, L3, L4, L5, L6, and L7. A read window budget (RWB) can refer to a cumulative value of read windows for a group of programmed cells (e.g., one or more pages of cells). In this example, the RWB can be the cumulative value (e.g., in voltage) of the seven read windows 320-326 between the eight Vt distributions.

FIG. 4 is a timing diagram depicting a portion of a programming operation to program selected TLC memory cells to target Vt levels L0 to L7 (e.g., as illustrated in FIG. 3) according to an embodiment. Once a selected memory cell has been programmed to its target Vt level, the memory cell is inhibited from further programming. Prior to time t0, memory cells selected for programming can be erased such that the selected memory cells each have a threshold voltage corresponding to level L0. At time t0, a first programming pulse is applied to a selected access line (e.g., 202 of FIG. 2A) connected to the control gates (e.g., 236) of the selected memory cells (e.g., 208). After the first programming pulse, a program verify operation can be performed to verify whether a target population of the selected memory cells has been programmed to level L1 or L2. At time t1, a second programming pulse, e.g., higher than the first programming pulse, is applied to the selected access line connected to the control gates of the selected memory cells. After the second programming pulse, a program verify operation can be performed to verify whether target populations of the selected memory cells have been programmed to Vt level L1 or L2.

At time t2, a third programming pulse, e.g., higher than the second programming pulse, is applied to the selected access line connected to the control gates of the selected memory cells. After the third programming pulse, a program verify operation can be performed to verify whether target populations of the selected memory cells have been programmed to level Vt L1, L2, or L3. At time t3, a fourth programming pulse, e.g., higher than the third programming pulse, is applied to the selected access line connected to the control gates of the selected memory cells. After the fourth programming pulse, a program verify operation can be performed to verify whether target populations of the selected memory cells have been programmed to Vt level L2, L3, or L4. At time t4, a fifth programming pulse, e.g., higher than the fourth programming pulse, is applied to the selected access line connected to the control gates of the selected memory cells. After the fifth programming pulse, a program verify operation can be performed to verify whether target populations of the selected memory cells have been programmed to Vt level L2, L3, L4, or L5.

At time t5, a sixth programming pulse, e.g., higher than the fifth programming pulse, is applied to the selected access line connected to the control gates of the selected memory cells. After the sixth programming pulse, a program verify operation can be performed to verify whether target populations of the selected memory cells have been programmed to Vt level L3, LA, L5, or L6. At time t6, a seventh programming pulse, e.g., higher than the sixth programming pulse, is applied to the selected access line connected to the control gates of the selected memory cells. After the seventh programming pulse, a program verify operation can be performed to verify whether target populations of the selected memory cells have been programmed to Vt level L3, L4, L5, L6, or L7. At time t7, an eighth programming pulse, e.g., higher than the seventh programming pulse, can be applied to the selected access line connected to the control gates of the selected memory cells and the process can repeat until the selected memory cells have been programmed to their target levels.

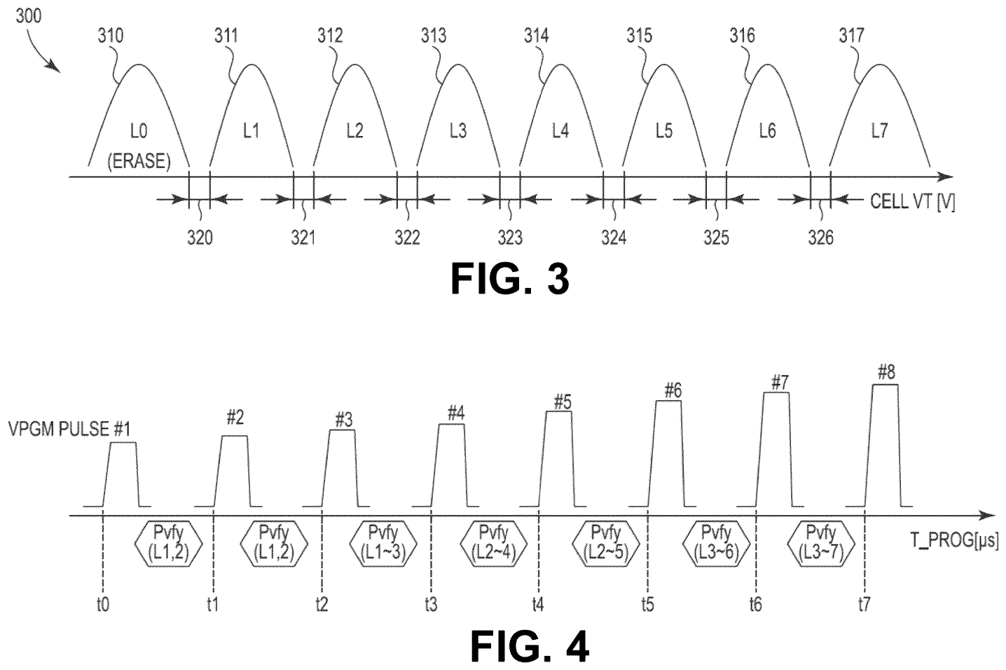

FIG. 5 is a diagrammatic illustration that depicts pulse breakpoints and corresponding resume points according to at least one embodiment. As illustrated, after a prologue period, a programming pulse is applied to a set of memory cells being programmed with multiple data states. Thus, these memory cells can be configured as multi-level cell memory. For these pulse breakpoint embodiments, the breakpoints generally follow each programming pulse but come before a corresponding program verify (PV) operation. The resume points are generally positioned directly after the breakpoint, thus re-entering at almost the same point that the programming was suspended. While using pulse breakpoints conserves time, doing so also makes it difficult to track Vt values for the memory cells since there is no program verify operation performed before the suspend operation. As discussed, this typically causes program voltage overshoot upon resume.

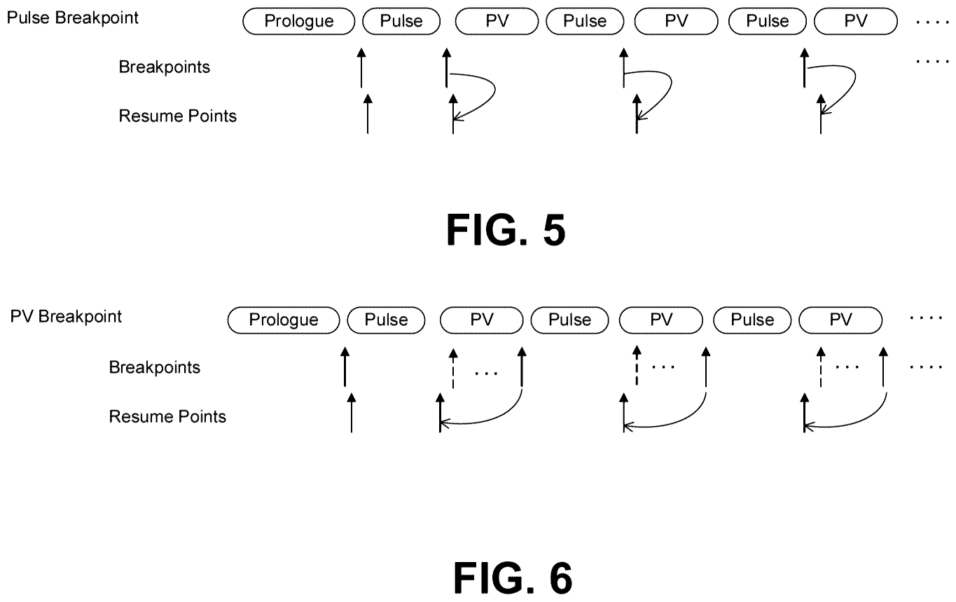

FIG. 6 is a diagrammatic illustration that depicts program verify (PV) breakpoints and corresponding resume points according to at least one embodiment. As illustrated, the PV breakpoints differ from the pulse breakpoints (FIG. 5) by being located after the program verify operations (see the solid arrows). Although a single “PV” block is illustrated, it should be understood that each PV block (particularly after the first PV block) can include multiple program verify operations, one for each data state (or level) that needs to be verified before a subsequent programming pulse is allowed to be applied to a subset of memory cells for each respective data state. For example, once the subset of memory cells for a data state reaches the PV target voltage, an inhibit bias voltage is applied to bitlines of that particular subset of memory cells so as not to further program programmed-verified memory cells.

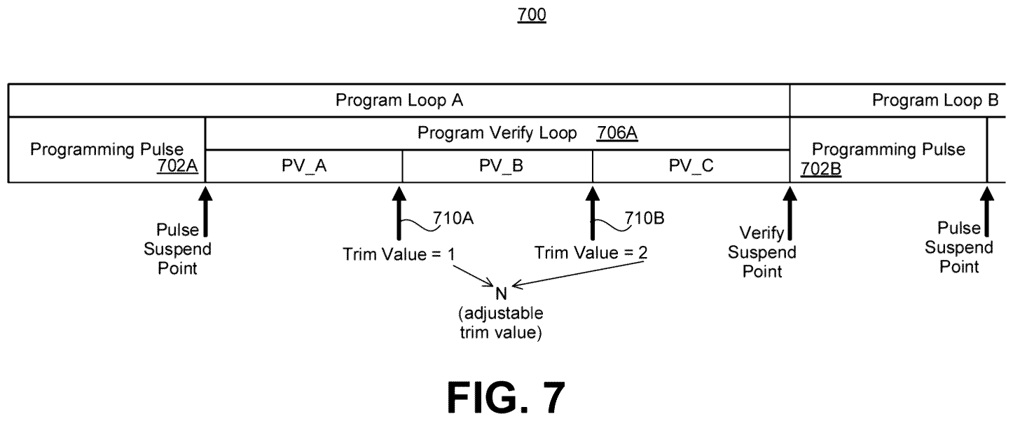

The resume points of FIG. 6, however, are located before the program verify operation, so that the program verify operation can be repeated after the delay of the suspend operation. In this way, the memory device 130 can determine downshift in Vt (of at least some of the memory cells) and properly classify the SSPC-based progress of the memory cells so as to avoid the program overshoot problem. As is illustrated and discussed in more detail with reference to FIG. 7, the present disclosure proposes to add verify loop suspend point(s) (e.g., see dashed arrows) during each program verify loop made up of a total number of program verify operations performed between programming pulses. In this way, at least one or more program verify operations can be performed without having to perform all of a total number of program verify operations between programming pulses and before suspend.

FIG. 7 is a diagrammatic illustration 700 that depicts customizable trim values that enable reduction of wait time to suspend with a variable number of program verify operations prior to suspend according to some embodiments. For example, the diagrammatic illustration 700 depicts a first program loop (A) and the beginning of a second program loop (B), each of which can be understood to be a programming pulse followed by a total number of program verify operations for the data states being programmed during an iteration of SSPC-based programming (see FIG. 4). Although the total number of program verify operations can vary as discussed with reference to FIG. 4, for purposes of explanation, the first program loop (A) includes a first programming pulse 702A and a first program verify loop 706A containing three program verify operations (PV_A, PV_B, and PV_C). The second program loop (B) can include a second programming pulse 702B and a further total number of program verify operations, which although not illustrated, could be of the same or different number than the three program verify operations of the first program verify loop 706A.

In some embodiments, each respective program verify operation of the total number of program verify operations is associated with a different data state that is being verified. Thus, for example, with reference to FIG. 4 and an example of TLC-based memory, the total number of program verify operations can be (L1, L2), (L1, L2, L3), (L2, L3, L4), (L3, L4, L5, L6), or the like. In this way, the data states associated with the total number of program verify operations that are to be performed between the first and second programming pulses 702A and 702B (or any two sequential programming pulses) can vary. As illustrated, however, in addition to a typical pulse suspend point and verify suspend point discussed with reference to FIGS. 5-6, the diagrammatic illustration 700 includes the addition of multiple verify loop suspend points within the first program verify loop 706A (e.g., which may be referred to herein as a present program verify loop). For example, there can be a first verify loop suspend point 710A associated with a trim value of one (“1”) and a second verify loop suspend point 710B associated with a trim value of two (“2”). Although not illustrated, there can be a third verify loop suspend point associated with a trim value of (“3”). Thus, for example, if the trim value is set to two, although there are a total number of three program verify operations, the local media controller 135 can cause only two program verify operations to be performed before suspend.

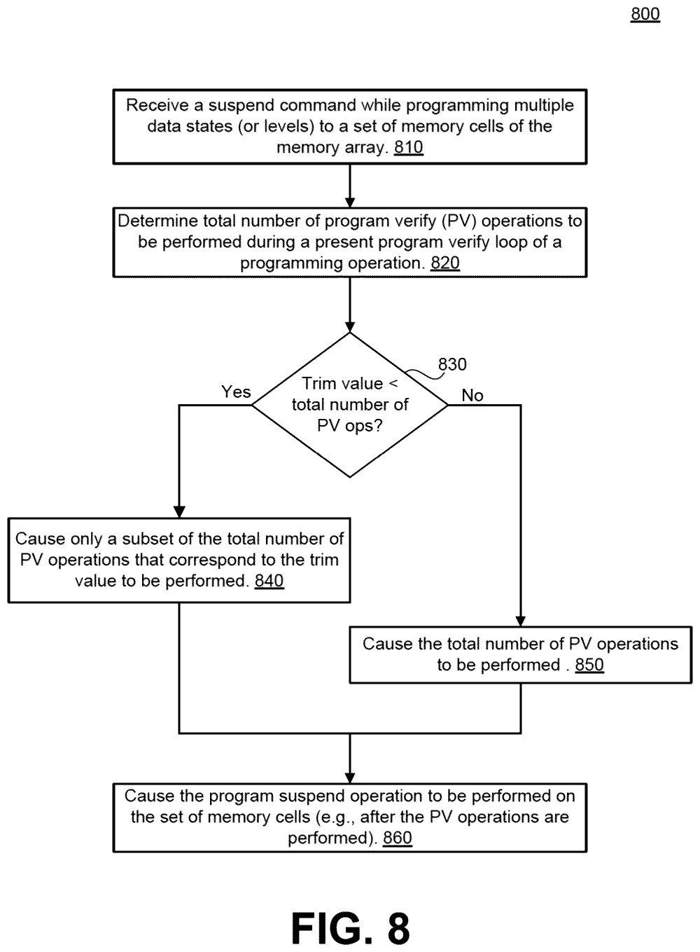

In this way, a trim value of “N” can be selectively programmed to the memory device 130 (e.g., with other trim values that impact memory device functionality) to be used by the local media controller 135 to determine, in comparison with the total number of program verify operations to be performed after the programming pulse 702A (see FIG. 8), a subset of the total number of program operations to be performed before causing a program suspend operation to be performed on the set of memory cells. Thus, the trim value may correspond to a sequential number of the program verify operations of the total number of program verify operations that are to be performed before suspending programming in response to a suspend command. The sequential number may be understood to sequentially relate to increasing data state levels for which the program verify operations are performed. For example, if the total number of program verify operations include (L2, L3, L4) and the trim value is two (“2”) for memory cells being programmed, the local media controller 135 can cause program verify operations to be performed on subsets of memory cells being programmed with data states L2 and L3, skipping the program verify operation for memory cells being programmed with data state L4. Many other example scenarios would be apparent to those skilled in the art given this disclosure.

Further by way of example, if the trim value is set to one (“1”), whether the suspend command is received during the first programming pulse 702A or the first program verify operation (PV_A), the control logic of the memory device 130 can activate a program suspend operation (e.g., suspend programming) at the first verify loop suspend point 710A. Similarly, if the trim value is set to two (“2”), the control logic can activate a program suspend operation (e.g., suspend programming) at the second verify loop suspend point 710B. Thus, the number of program verify operations performed before the suspend can be customized in order to both capture Vt information useable in SSPC-based programming and save in wait time to suspend by being able to skip a remainder of the total program verify operations. In this way, the trim value can be customized and programmed to the memory device 130 based on particular criteria, such as speed of programming of different memory cells (e.g., associated with different pages, super pages, sub-blocks, super sub-blocks, blocks, or super blocks of memory cells), number of data states (and thus type of multi-level cell memory), different applications, and the like.

FIG. 8 is a flow diagram of an example method 800 of determining a number of program verify operations to perform within a program verify loop before suspend based on a trim value and a total number of program verify operations according to some embodiments. The method 800 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 800 is performed by the local media controller 135 (or control logic) of FIGS. 1A-1B that includes instructions registers 128. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 810, a suspend command is received. For example, the processing logic (e.g., local media controller 135) receives a suspend command while programming multiple data states to a set of the plurality of memory cells of a memory array (such as the array of memory cells 104 of FIG. 1B). In some embodiments, receiving the suspend command occurs during one of a programing pulse being applied to the set of plurality of memory cells or performing the present program verify loop that follows the programming pulse.

At operation 820, a total number of program verify (PV) operations is determined. For example, the processing logic determines the total number of program verify operations to be performed during a present program verify loop of a programming operation. This could be, for example, one of the program verify loops discussed with reference to FIG. 4 and FIG. 7.

At operation 830, a trim value is compared to the total number of program verify operations. For example, the processing logic determines whether a trim value associated with a program suspend operation is less than the total number of program verify operations to be performed during a present program verify loop of a programming operation. As discussed, the present program verify loop may occur between two programming pulses of SSPC-based programming.

At operation 840, a subset of program verify operations is performed. For example, in response to the trim value being less than the total number of program verify operations at operation 830, the processing logic causes only a subset of the total number of program verify operations that correspond to the trim value to be performed before causing a program suspend operation to be performed on the set of plurality of memory cells. In some embodiments, causing only the subset of the total number of program verify operations to be performed includes skipping a remainder of the total number of program verify operations, each being numbered as greater than the trim value, before causing the program suspend operation to be performed on the set of plurality of memory cells.

At operation 850, the total number of program verify operations is performed. For example, in response to the trim value being greater than or equal to the total number of program verify operations at operation 830, the processing logic causes the total number of program verify operations to be performed before causing the program suspend operation to be performed on the set of plurality of memory cells.

At operation 860, a program suspend operation is performed. For example, the processing logic causes the program suspend operation to be performed on the set of memory cells, e.g., after the program verify operations associated with the trim value are performed. More specifically, the processing logic can enter a suspend period of a predetermined time duration as a part of the program suspend operation. The processing logic can further, in response to exiting the suspend period, causing a resume operation to be performed that begins before the program verify loop, as discussed in relation to FIG. 6. In some embodiments, upon resume of the programming, each program verify operation within the program verify loop 706A (FIG. 7) is performed. In some embodiments, the processing logic further causes a resume-to-suspend minimum time period to be observed after the resume operation begins and before acting to comply with a new suspend command. This minimum time period may be set to ensure a balance between forward progress of a pending programming operation and the non-programming prioritized operations such as read operations.

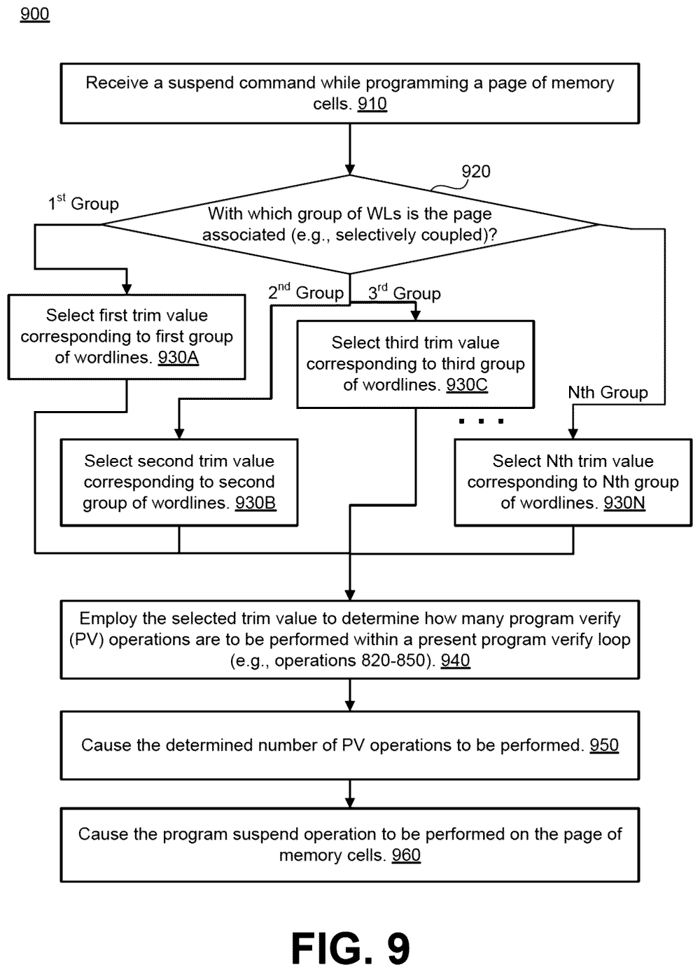

FIG. 9 is a flow diagram of an example method 900 of selectively choosing a trim value, based on a page belonging to a particular group of wordlines, for use in determining how many program verify operations to perform before suspend according to some embodiments. The method 900 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 900 is performed by the local media controller 135 (or control logic) of FIGS. 1A-1B that includes instructions registers 128. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

As discussed, the trim value referenced herein may vary across different sets of memory cells (e.g., associated with different pages, super pages, sub-blocks, super sub-blocks, blocks, or super blocks of memory cells) of a memory array based on different speeds of programming. This phenomenon can be especially relevant in 3D memory such as 3D NAND, where some wordline groups (depending on depth location along a pillar) may be programmed with a shorter or longer pulse or verify duration than other wordline groups that also impacts wait times to suspend. In these situations, the trim value for at least some of the wordline groups may be customized in order to accommodate different wordline groups with different pulse and verify durations, to have shorter wait times to suspend within the target requirement. In this way, wait time to suspend can still be reduced while further preventing program overshoot that may be of higher risk in memory cells coupled to wordline of a wordline group that experiences faster charge loss.

At operation 910, a suspend command is received. More specifically, the processing logic (e.g., the local media controller 135) receives a suspend command while programming multiple data states to a page of a plurality of memory cells of a memory array.

At operation 920, a wordline group is identified. For example, the processing logic determines with which group of wordlines of a plurality of wordlines is the page of the plurality of memory cells associated.

At operation 930A, a first trim value is selected. For example, in response to the page of the plurality of memory cells being associated with a first group of wordlines, the processing logic selects a first trim value corresponding to the first group of wordlines as a selected trim value.

At operation 930B, a second trim value is selected. For example, in response to the page of the plurality of memory cells being associated with a second group of wordlines, the processing logic selects a second trim value corresponding to the second group of wordlines as the selected trim value.

At operation 930C, a third trim value is selected. For example, in response to the page of the plurality of memory cells being associated with a third group of wordlines, the processing logic selects a third trim value corresponding to the third group of wordlines as the selected trim value. As is apparent, operation 930C can be repeated up and to operation 930N for additional granularities of wordline groups having sufficiently different pulse and verify durations from other wordline groups.

At operation 930N, an Nth trim value is selected. For example, in response to the page of the plurality of memory cells being associated with an Nth group of wordlines, the processing logic selects an Nth trim value corresponding to the Nth group of wordlines as the selected trim value.

At operation 940, the selected trim value is used. More specifically, the processing logic employs the selected trim value (e.g., from operations 930A-930N) to determine how many program verify operations are to be performed within a present program verify loop before causing a program suspend operation to be performed on the page of the plurality of memory cells in response to the suspend command. In at least some embodiments, the determination of operation 940 may be performed as specified at operations 820 through 850 of the method 800 (FIG. 8).

At operation 950, the program verify operations are performed. For example, the processing logic causes the determined number of program verify operations (from operation 940) to be performed.

At operation 960, a program suspend operation is performed. For example, the processing logic causes the program suspend operation to be performed (or activated) on the page of memory cells, e.g., after operation 950 is completed.

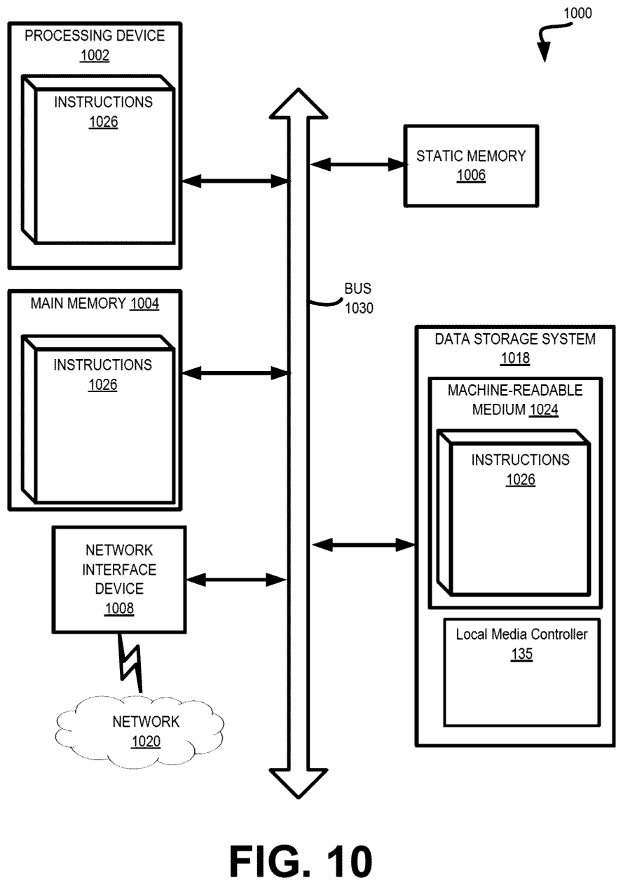

FIG. 10 illustrates an example machine of a computer system 1000 within which a set of instructions, for causing the machine to perform any one or more of the methodologies discussed herein, can be executed. In some embodiments, the computer system 1000 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the local media controller 135 of FIG. 1A), also referred to as control logic herein. In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1000 includes a processing device 1002, a main memory 1004 (e.g., read-only memory (ROM), flash memory, dynamic random access memory (DRAM) such as synchronous DRAM (SDRAM) or Rambus DRAM (RDRAM), etc.), a static memory 1010 (e.g., flash memory, static random access memory (SRAM), etc.), and a data storage system 1018, which communicate with each other via a bus 1030.

Processing device 1002 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1002 can also be one or more special-purpose processing devices such as an application specific integrated circuit (ASIC), a field programmable gate array (FPGA), a digital signal processor (DSP), network processor, or the like. The processing device 1002 is configured to execute instructions 1028 for performing the operations and steps discussed herein. The computer system 1000 can further include a network interface device 1012 to communicate over the network 1020.

The data storage system 1018 can include a machine-readable storage medium 1024 (also known as a computer-readable medium) on which is stored one or more sets of instructions 1028 or software embodying any one or more of the methodologies or functions described herein. The data storage system 1018 can further include the local media controller 135, which were previously discussed. The instructions 1028 can also reside, completely or at least partially, within the main memory 1004 and/or within the processing device 1002 during execution thereof by the computer system 1000, the main memory 1004 and the processing device 1002 also constituting machine-readable storage media. The machine-readable storage medium 1024, data storage system 1018, and/or main memory 1004 can correspond to the memory sub-system 110 of FIG. 1A.

In one embodiment, the instructions 1026 include instructions to implement functionality corresponding to a controller (e.g., the memory sub-system controller 115 of FIG. 1A). While the machine-readable storage medium 1024 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., non-transitory computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of memory cells; and
control logic operatively coupled with the memory array, the control logic to perform operations comprising:
receiving a suspend command while programming multiple data states to a set of the plurality of memory cells of the memory array;
determining whether a trim value associated with a program suspend operation is less than a total number of program verify operations to be performed during a present program verify loop of a programming operation; and
in response to the trim value being less than the total number of program verify operations, causing only a subset of the total number of program verify operations that correspond to the trim value to be performed before causing a program suspend operation to be performed on the set of plurality of memory cells.

2. The memory device of claim 1, wherein the subset of the total number of program verify operations are those program verify operations that are sequentially numbered as less than the trim value within the present program verify loop.

3. The memory device of claim 1, wherein causing only the subset of the total number of program verify operations to be performed comprises skipping a remainder of the total number of program verify operations, each being numbered as greater than the trim value, before causing the program suspend operation to be performed on the set of plurality of memory cells.

4. The memory device of claim 1, wherein each respective program verify operation of the total number of program verify operations is associated with a different data state that is being verified.

5. The memory device of claim 1, wherein the operations further comprise, in response to the trim value being greater than or equal to the total number of program verify operations, causing the total number of program verify operations to be performed before causing the program suspend operation to be performed on the set of plurality of memory cells.

6. The memory device of claim 1, wherein the operations further comprise:
entering a suspend period of a predetermined time duration as a part of the program suspend operation; and
in response to exiting the suspend period, causing a resume operation to be performed that begins before the program verify loop.

7. The memory device of claim 6, wherein the operations further comprise causing a resume-to-suspend minimum time period to be observed after the resume operation begins and before acting to comply with a new suspend command.

8. The memory device of claim 1, wherein receiving the suspend command occurs during one of a programing pulse being applied to the set of plurality of memory cells or performing the present program verify loop that follows the programming pulse.

9. The memory device of claim 1, wherein the set of plurality of memory cells comprises a page of the plurality of memory cells, and wherein the operations further comprise:
determining with which group of wordlines of a plurality of wordlines is the page of the plurality of memory cells associated;
in response to the page of the plurality of memory cells being associated with a first group of wordlines, using a first trim value corresponding to the first group of wordlines; and
in response to the page of the plurality of memory cells being associated with a second group of wordlines, using a second trim value corresponding to the second group of wordlines.

10. A method comprising:
receiving, by control logic of a memory device, a suspend command while programming multiple data states to a set of a plurality of memory cells of a memory array;
determining whether a trim value associated with a program suspend operation is less than a total number of program verify operations to be performed during a present program verify loop of a programming operation; and
in response to the trim value being less than the total number of program verify operations, causing only a subset of the total number of program verify operations that correspond to the trim value to be performed before causing a program suspend operation to be performed on the set of plurality of memory cells.

11. The method of claim 10, wherein the subset of the total number of program verify operations are those program verify operations that are sequentially numbered as less than the trim value within the present program verify loop.

12. The method of claim 10, wherein causing only the subset of the total number of program verify operations to be performed comprises skipping a remainder of the total number of program verify operations, each being numbered as greater than the trim value, before causing the program suspend operation to be performed on the set of plurality of memory cells.

13. The method of claim 10, wherein each respective program verify operation of the total number of program verify operations is associated with a different data state that is being verified.

14. The method of claim 10, further comprising, in response to the trim value being greater than or equal to the total number of program verify operations, causing the total number of program verify operations to be performed before causing the program suspend operation to be performed on the set of plurality of memory cells.

15. The method of claim 10, further comprising:
entering a suspend period of a predetermined time duration as a part of the program suspend operation; and
in response to exiting the suspend period, causing a resume operation to be performed that begins before the program verify loop.

16. The method of claim 15, further comprising causing a resume-to-suspend minimum time period to be observed after the resume operation begins and before acting to comply with a new suspend command.

17. The method of claim 10, wherein receiving the suspend command occurs during one of a programing pulse being applied to the set of plurality of memory cells or performing the present program verify loop that follows the programming pulse.

18. The method of claim 10, wherein the set of plurality of memory cells comprises a page of the plurality of memory cells, the method further comprising:
determining with which group of wordlines of a plurality of wordlines is the page of the plurality of memory cells associated;
in response to the page of the plurality of memory cells being associated with a first group of wordlines, using a first trim value corresponding to the first group of wordlines; and
in response to the page of the plurality of memory cells being associated with a second group of wordlines, using a second trim value corresponding to the second group of wordlines.

19. A method comprising:
receiving, by control logic of a memory device, a suspend command while programming multiple data states to a page of a plurality of memory cells of a memory array;
determining with which group of wordlines of a plurality of wordlines is the page of the plurality of memory cells associated;
in response to the page of the plurality of memory cells being associated with a first group of wordlines, selecting a first trim value corresponding to the first group of wordlines as a selected trim value;
in response to the page of the plurality of memory cells being associated with a second group of wordlines, selecting a second trim value corresponding to the second group of wordlines as the selected trim value; and
employing, by the control logic, the selected trim value to determine how many program verify operations are to be performed within a present program verify loop before causing a program suspend operation to be performed on the page of the plurality of memory cells in response to the suspend command.

20. The method of claim 19, further comprising:
determining whether the selected trim value is less than a total number of program verify operations to be performed during the present program verify loop of a programming operation; and
in response to the selected trim value being less than the total number of program verify operations, causing only a subset of the total number of program verify operations that correspond to the selected trim value to be performed before causing a program suspend operation to be performed on the page of the plurality of memory cells.

21. The method of claim 20, further comprising, in response to the selected trim value being greater than or equal to the total number of program verify operations, causing the total number of program verify operations to be performed before causing the program suspend operation to be performed on the page of the plurality of memory cells.

22. The method of claim 19, further comprising, in response to the page of the plurality of memory cells being associated with an Nth group of wordlines, selecting an Nth trim value corresponding to the Nth group of wordlines as the selected trim value.
